(19) United States
(12) Patent Application Publication
(10) Pub. No.: US 2026/0142102 A1
(43) Pub. Date: May 21, 2026

(54) SWITCH STRUCTURE AND POWER SUPPLY DEVICE

(71) Applicant: Nissan Motor Co., Ltd., Yokohama-shi, Kanagawa (JP)

(72) Inventors: Shota KOMAKI, Kanagawa (JP); Masato SASOU, Kanagawa (JP); Tetsuya KAWAJIRI, Kanagawa (JP)

(21) Appl. No.: 19/123,410

(22) PCT Filed: Oct. 26, 2022
(86) PCT No.: PCT/JP2022/039911

§ 371 Date: Apr. 23, 2025

(51) Int. Cl. H01H 21/22; B60R 16/033; H05K 5/02

(52) U.S. Cl. CPC H01H 21/22; B60R 16/033; H05K 5/0217

(57) ABSTRACT

A switch structure includes a cutoff switch. The cutoff switch is configured to be manually operated to cut off a battery module from a drive system. A console box is configured to be disposed between a driver seat and a passenger seat. The cutoff switch is configured to be disposed inside the console box on a passenger seat side of the console box.

### CROSS-REFERENCE TO RELATED APPLICATIONS

This application is a U.S. national stage application of International Application No. PCT/JP 2022/039911, filed on Oct. 26, 2022.

### BACKGROUND

### Technical Field

The present invention relates to a switch structure and a power supply device, and more particularly to a mounting structure for a service disconnect switch that is manually operated to disconnect a battery from a power electronic system.

### Background Information

An automobile is equipped with a service disconnect switch (SD switch) that is manually operated to mechanically disconnect a battery power electronic circuit (see Japanese Patent Application Publication No. 2012-240476, hereinafter referred to as Patent Document 1). This SD switch can be manually switched on and off for inspection, repair, or parts replacement of a power electronic module, an inverter, or the like.

According to this conventional technology, the SD switch is disposed under the floor of a vehicle. To operate the SD switch, an operator removes a center console box from inside a compartment of the vehicle, then removes a cover covering a lever operation hole in the floor of the vehicle, and operates the SD switch under the floor of the vehicle through the lever operation hole (see paragraph [0041], FIGS. 10 and 11 of Patent Document 1).

### SUMMARY

There is a problem in such a conventional technology that the SD switch is disposed under the floor of the vehicle, making it difficult for an operator to operate the SD switch, resulting in poor operability.

An object of the present invention is to provide a switch structure and a power supply device that can improve operability.

The present invention solves the above-mentioned problem by disposing a cutoff switch inside a console box on a passenger seat side.

According to the present invention, the cutoff switch is disposed on the passenger seat side inside the console box, thereby improving operability.

### BRIEF DESCRIPTION OF DRAWINGS

Referring now to the attached drawings which form a part of this original disclosure, illustrative embodiments are shown.

FIG. 1 is a plan view illustrating a frame, a battery pack, and a steering mechanism of a vehicle, according to the present invention.

FIG. 2 is a perspective view illustrating the frame, a floor panel, and a console box of the vehicle, according to the present invention.

FIG. 3 is a perspective view illustrating a state in which the floor panel and the console box have been removed from the vehicle of FIG. 2, and is a perspective view illustrating a vehicle body, the battery pack, a DC-DC converter, and a cooling mechanism of the vehicle, according to the present invention.

FIG. 4 is a block diagram illustrating a cross section taken along line IV-IV in FIG. 3.

FIG. 5 is a block diagram illustrating a cross section taken along line V-V in FIG. 3.

FIG. 6 is a cross-sectional view illustrating an operation of a cutoff switch of a switch structure according to the present invention.

FIG. 7 is a perspective view illustrating a motion of a switch portion of the cutoff switch when a lever portion of the cutoff switch is operated as illustrated in FIG. 6.

### DETAILED DESCRIPTION OF EMBODIMENTS

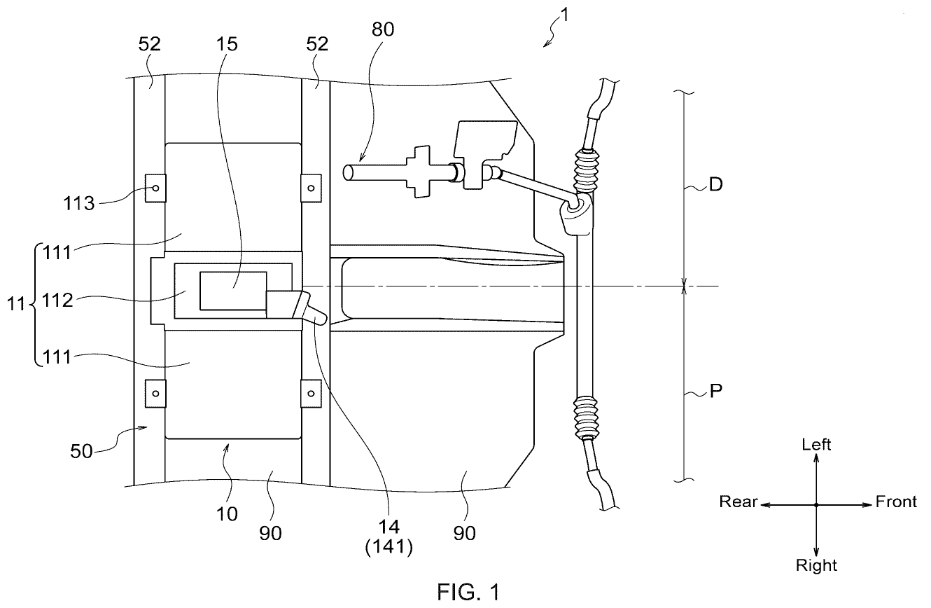

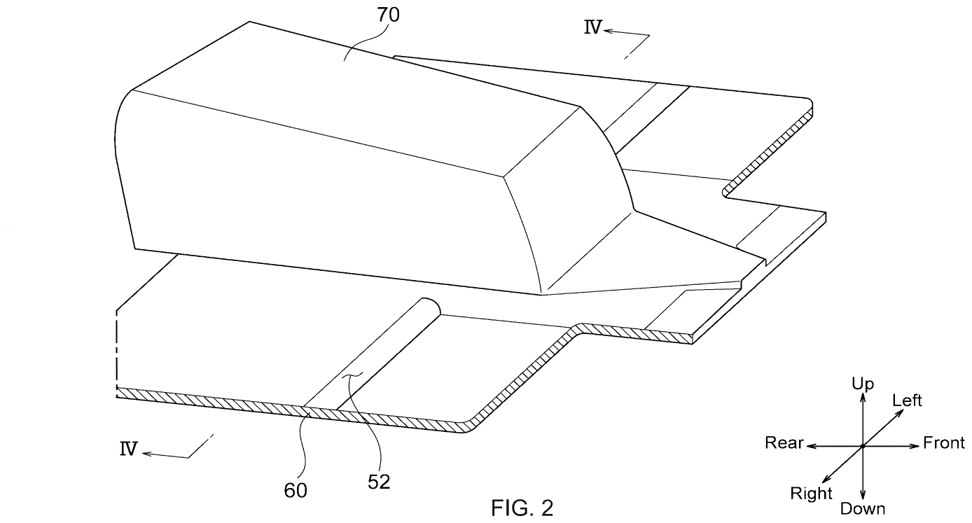

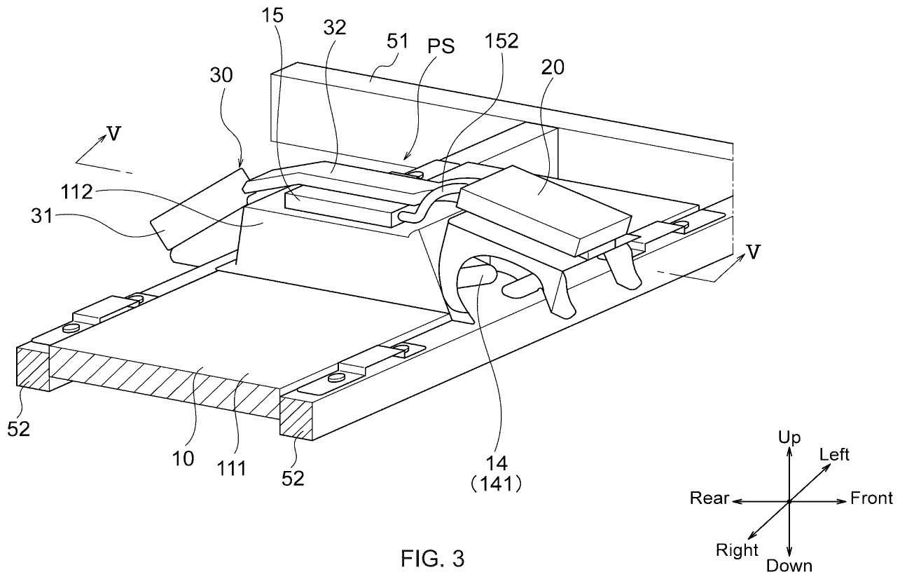

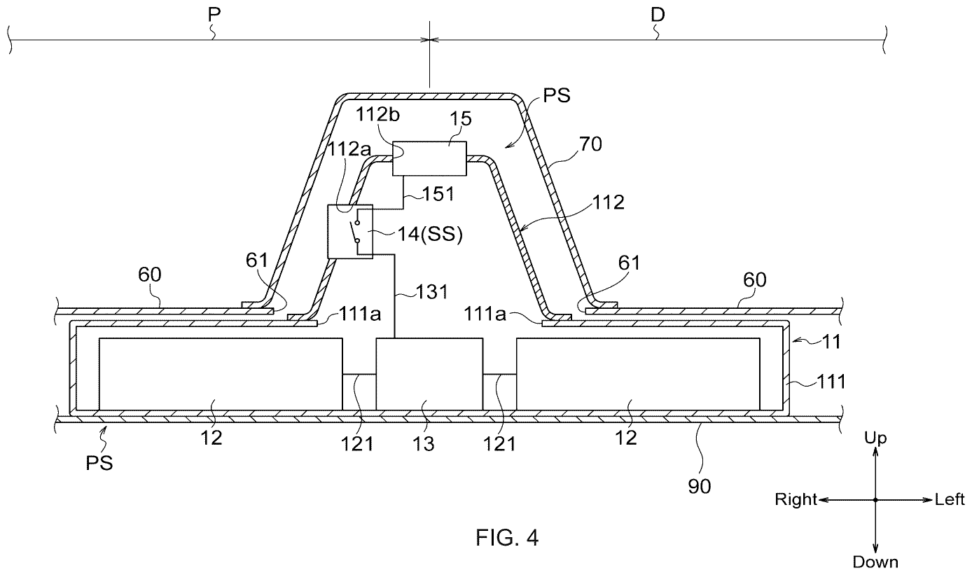

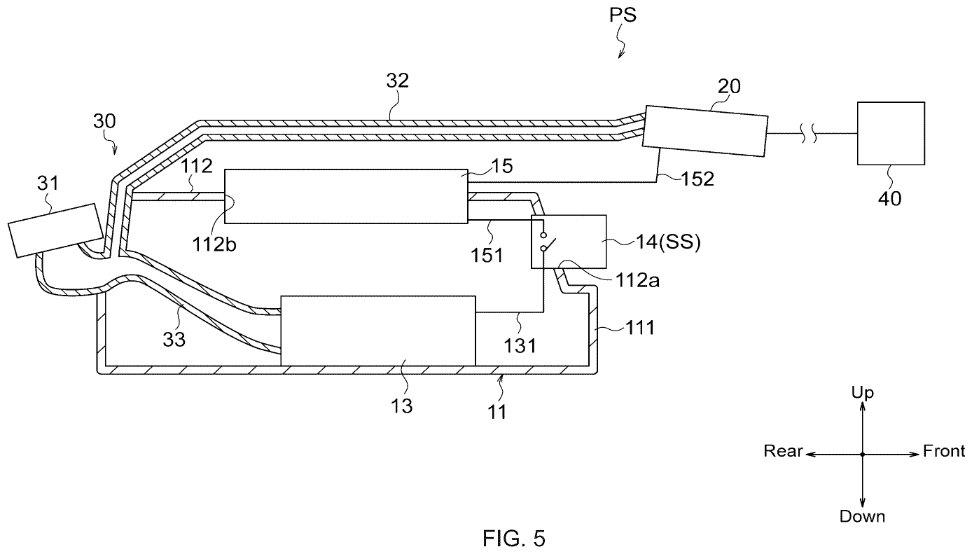

A vehicle 1 according to an embodiment of the present invention will be described with reference to the drawings. FIG. 1 is a plan view illustrating a frame 50, a battery pack 10, and a steering mechanism 80 of the vehicle 1 in the present embodiment. FIG. 2 is a perspective view illustrating the frame 50, a carpet 60, and a console box 70 of the vehicle 1 in the present embodiment. FIG. 3 is a perspective view illustrating a state in which the carpet 60 and the console box 70 have been removed from the vehicle 1 in FIG. 2, and is a perspective view illustrating the frame 50, the battery pack 10, a DC-DC converter 20, and a cooling mechanism 30 of the vehicle 1. FIG. 4 is a block diagram illustrating a cross section taken along line IV-IV in FIG. 2, and FIG. 5 is a block diagram illustrating a cross section taken along line V-V in FIG. 3.

The vehicle 1 in the present embodiment is, for example, an electric vehicle. As illustrated in FIGS. 1 and 2, the vehicle 1 includes the frame 50, the carpet 60, the console box 70 (see FIG. 2), the steering mechanism 80, and a floor panel 90. As illustrated in FIGS. 1 and 3, the frame 50 includes at least a side sill 51 and a plurality of cross members 52 fixed to the side sill 51.

As illustrated in FIG. 2, the carpet 60 constitutes a floor surface of a vehicle compartment. The carpet 60 is disposed on the cross members 52 of the frame 50, and extends inward from the side sill 51 and along the vehicle width direction of the vehicle 1 (the left-right direction in the figure). As illustrated in FIG. 4, the carpet 60 has an opening 61 formed in the center in the vehicle width direction between a driver seat D side and a passenger seat P side.

Note that the driver seat is the seat on the side where the steering mechanism 80 including a steering wheel (not illustrated), an accelerator pedal (not illustrated), and a brake pedal (not illustrated) are provided in the vehicle compartment, as illustrated in FIG. 1, and the passenger seat is the seat next to the driver seat. In the present embodiment, the left front seat of the vehicle 1 serves as the driver seat, but is not limited to this. The right front seat may be the driver seat, and the left front seat may be the passenger seat.

As illustrated in FIGS. 2 and 4, the console box 70 is disposed between the driver seat D and the passenger seat P so as to cover the opening 61. The lower portion of the console box 70 is removably fixed to the carpet 60 by a fastener (not illustrated). The console box 70 in the present embodiment also opens downward.

As illustrated in FIG. 3, the vehicle 1 further includes a power supply device PS that includes the battery pack 10, the DC-DC converter 20, and the cooling mechanism 30.

As illustrated in FIG. 4, the battery pack 10 is disposed under the floor of the vehicle compartment (below the carpet 60). More specifically, a lower member 111 of the battery pack 10 is disposed below the carpet 60, and an upper member 112 of the battery pack 10 is disposed inside the console box 70. Further, as illustrated in FIGS. 1 and 4, the battery pack 10 is disposed on the floor panel 90.

The battery pack 10 includes a module case 11, a plurality of battery modules 12, a junction box 13, a cutoff switch 14, and a battery controller 15.

The module case 11 is a case in which the components that make up the battery pack 10 are mounted. This module case 11 is provided with the plurality of battery modules 12, the junction box 13, the cutoff switch 14, and the battery controller 15.

The module case 11 has the lower member 111, the upper member 112, and a plurality of brackets 113. The lower member 111 is a hollow housing that houses the plurality of battery modules 12 and the junction box 13 therein. The module case 11 has an opening 111a in an approximate center region of its upper surface.

The upper member 112 is disposed so as to cover this opening 111a. The upper member 112 is located inside the console box 70 and is a plate-like member that protrudes upward following the shape of the console box 70. This upper member 112 makes up a part of the upper surface of the module case 11. The upper member 112 in the present embodiment corresponds to an example of a “protrusion” in the present invention.

The cutoff switch 14 is disposed in an opening 112a on a side surface of this upper member 112, while the battery controller 15 is disposed in an opening 112b on the upper surface of the upper member 112.

As illustrated in FIG. 1, the plurality of brackets 113 extend from side surfaces of the module case 11 so as to overlap with the cross members 52. These brackets 113 are fixed to the cross members 52 by fasteners such as bolts (not illustrated), thereby fixing the battery pack 10 to the cross members 52.

As illustrated in FIG. 4, the plurality of battery modules 12 are mounted inside the lower member 111 of the module case 11. Although not specifically illustrated, in each battery module 12, a plurality of battery cells are stacked one on another, and adjacent battery cells are electrically connected to each other via bus bars or the like.

The plurality of battery modules 12 are electrically connected to the junction box 13 via wires 121. The junction box 13 is disposed between the plurality of battery modules 12 and is disposed inside the lower member 111 and below the upper member 112. The junction box 13 is a device for electrically branching the wires 121 of the battery modules 12.

As illustrated in FIGS. 4 and 5, the junction box 13 is electrically connected to the cutoff switch 14 via a wire 131. As illustrated in FIG. 4, the cutoff switch 14 is provided in the opening 112a on the side surface of the upper member 112 on the passenger seat P side. As a result, the cutoff switch 14 is disposed inside the console box 70 on the passenger seat P side.

This cutoff switch 14 constitutes a switch structure SS, and is a switch that can be manually operated by an operator to cut off the battery modules 12 from power electronic components (including a drive system 40 in FIG. 5) when assembling the vehicle 1, when maintaining the vehicle 1, when an emergency occurs, and the like. In the present embodiment, the electrical connection between the junction box 13 and the battery controller 15 is cut off by the cutoff switch 14, thereby electrically isolating the battery modules 12 from the power electronic components. The power electronic components correspond to electronic components including the DC-DC converter 20 and/or the drive system, which are electrically connected to the battery modules 12.

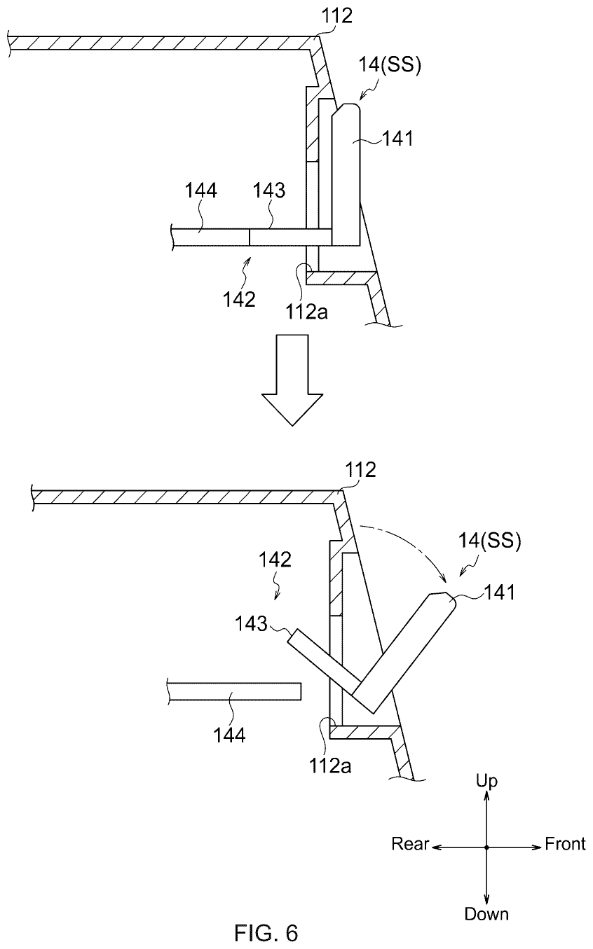

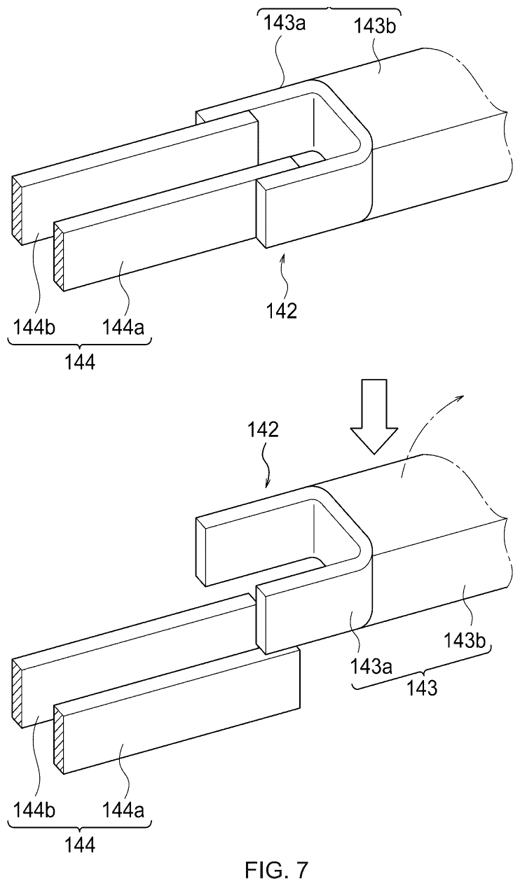

FIG. 6 is a cross-sectional view illustrating an operation of the cutoff switch 14 of the switch structure SS of the present embodiment. FIG. 7 is a perspective view illustrating a motion of a switch portion 142 when a lever portion 141 of the cutoff switch 14 is operated as illustrated in FIG. 6.

As illustrated in FIG. 6, the cutoff switch 14 in the switch structure SS has the lever portion 141 and the switch portion 142. The lever portion 141 is a movable part that is directly operated by the operator. The lever portion 141 in the present embodiment is set to be movable in the vertical direction, and as illustrated in the upper drawing of FIG. 6, is disposed so as to extend upward in the home position (ON position).

The switch portion 142 is a part that switches the electrical connection ON/OFF in conjunction with the motion of the lever portion 141. This switch portion 142 includes a lever-side switch portion 143 and a circuit-side switch portion 144.

The lever-side switch portion 143 is physically connected to the lever portion 141 and moves in response to the operation of the lever portion 141. As illustrated in the lower diagram of FIG. 6, the lever-side switch portion 143 in the present embodiment is configured so as to rise upward, opposite to the lever portion 141, when the lever portion 141 is pressed down.

As illustrated in FIG. 7, the lever-side switch portion 143 includes an interposed portion 143a and a connecting portion 143b. The interposed portion 143a is a portion interposed between the lever portion 141 and the connecting portion 143b, and is made of a non-conductive material. The connecting portion 143b is disposed at the tip of the interposed portion 143a, and is made of a conductive material such as a metal. As illustrated in the upper diagram of FIG. 7, the connecting portion 143b in the present embodiment has, but not limited to, a substantially U-shape, and when the lever portion 141 is located in the ON position, comes into contact with both a battery-side conductor 144a and a controller-side conductor 144b of a circuit-side switch portion 144, which will be described below, to electrically connect the two.

The circuit-side switch portion 144 includes the battery-side conductor 144a and the controller-side conductor 144b. The battery-side conductor 144a in the present embodiment is electrically connected to the wire 131 on the junction box 13 side, and the controller-side conductor 144b is electrically connected to a wire 151 on the battery controller 15 side.

As illustrated in the upper diagram of FIG. 6 and the upper diagram of FIG. 7, when the lever portion 141 is in the ON position, the connecting portion 143b comes into contact with both the battery-side conductor 144a and the controller-side conductor 144b of the circuit-side switch portion 144 to electrically connect the two. On the other hand, when the lever portion 141 is moved downward from above to be positioned in the OFF position, the lever-side switch portion 143 rises upward in conjunction with the lever portion 141, so that the connecting portion 143b moves away from the battery-side conductor 144a and the controller-side conductor 144b. As a result, the electrical connection between the battery-side conductor 144a and the controller-side conductor 144b is disconnected, and the electrical connection between the junction box 13 and the battery controller 15 is disconnected accordingly. Consequently, the battery modules 12 are disconnected from the power electronic components.

In the present embodiment, since the battery modules 12 can be disconnected from the power electronic components by moving the lever portion 141 downward from above, the operator can operate the lever portion 141 to turn OFF the cutoff switch 14 simply by lowering his or her hand downward from the home position of the lever portion 141. With the vehicle 1 having this cutoff switch 14, the operator does not need to reach further to perform an operation such as pulling the lever portion 141 from the rear side to the front side, thereby improving operability.

Further, as illustrated in FIG. 1, when viewed in a plan view, the lever portion 141 of the cutoff switch 14 is inclined with respect to the width direction of the vehicle 1 (the left-right direction in the figure) and with respect to the front-rear direction of the vehicle 1, and extends toward the door on the passenger seat P side. In other words, when viewed in a plan view, the lever portion 141 is located between the vehicle width direction and the front-rear direction of the vehicle 1, and the extension direction of the lever portion 141 is not parallel to either the vehicle width direction or the front-rear direction on the passenger seat P side, but is inclined toward the door on the passenger seat side. In this way, the lever portion 141 is inclined toward the door on the passenger seat side and is not parallel to the vehicle width direction when viewed in a plan view, and therefore the lever portion 141 does not interfere with a seat rail for positioning the seat, thereby improving operability. In addition, since the lever portion 141 is inclined in the front-rear direction and extends toward the door on the passenger seat side when viewed in a plan view, the operator can easily operate the lever portion 141 from the passenger seat side where there is no interference from the steering wheel or pedals, thereby improving operability.

As illustrated in FIG. 4, the battery controller 15 is connected to the cutoff switch 14 via the wire 151. This battery controller 15 is provided in the opening 112b on the upper surface of the upper member 112 of the module case 11. The battery controller 15 is a computer (ECU) that controls the charging and discharging of the battery modules 12.

As illustrated in FIG. 5, at least a portion of the battery controller 15 is exposed to the outside of the module case 11 through the opening 112b and is electrically connected to the DC-DC converter 20 located outside the module case 11 via a wire 152.

The DC-DC converter 20 is a device for converting a direct current to a direct current. The DC-DC converter 20 is electrically connected to the drive system 40 including an inverter, a motor, and the like. Although not limited thereto, the inverter, the drive motor, and the like are disposed in a hood at the front of the vehicle.

As illustrated in FIG. 5, the cooling mechanism 30 is provided behind the upper member 112 of the module case 11. The cooling mechanism 30 cools the junction box 13 and the DC-DC converter 20.

The cooling mechanism 30 includes a fan 31, an upper duct 32, and a lower duct 33. The fan 31 is provided behind the upper member 112 of the module case 11, and blows air into the upper duct 32 and the lower duct 33.

As illustrated in FIG. 3, the upper duct 32 is provided above the upper member 112 and the battery controller 15, and extends along the front-rear direction of the vehicle 1. The upper duct 32 is a hollow tubular member, and sends air from the fan 31 to the DC-DC converter 20. As illustrated in FIG. 3, the battery controller 15 and the upper duct 32 are arranged inside the console box 70 side by side along the vertical direction, so that the cutoff switch 14 can be disposed in the space below the battery controller 15 and the upper duct 32, thereby reducing the space occupied by the battery controller 15, the upper duct 32, and the cutoff switch 14 inside the console box 70.

On the other hand, as illustrated in FIG. 5, the lower duct 33 is provided so as to enter the inside of the module case 11, and extends along the front-rear direction of the vehicle 1. The lower duct 33 is a hollow tubular member, and sends air from the fan 31 to the junction box 13.

As described above, in the vehicle 1 of the present embodiment, the cutoff switch 14 is disposed inside the console box 70 on the passenger seat P side, thereby improving operability with which the operator operates the cutoff switch 14.

1. A switch structure comprising:
a cutoff switch configured to be manually operated to cut off a battery module from a power electronic component, wherein
the cutoff switch is disposed on a side of a passenger seat inside a console box disposed between a driver seat and the passenger seat of a vehicle,
the cutoff switch includes a lever portion that is inclined toward a door adjacent to the passenger seat.

2. The switch structure according to claim 1, wherein
the lever portion is movable in a vertical direction, and
the cutoff switch cuts off the battery module from the power electronic component by moving the lever portion downward from above.

3. The switch structure according to claim 2, wherein
the lever portion is not parallel to a vehicle width direction of the vehicle and not parallel to a front-rear direction of the vehicle inclined as viewed in a plan view.

4. A power supply device including the switch structure according to claim 1, the power supply device comprising:
a battery controller configured to control the battery module;
a DC-DC converter; and
a duct configured to send air to the DC-DC converter,
wherein the battery controller and the duct are arranged along a vertical direction inside the console box.

5. The power supply device according to claim 4, further comprising
a module case in which the battery module is mounted,
wherein an upper surface of the module case has a protrusion located inside the console box, and
the cutoff switch is provided on a side surface of the protrusion.

6. A power supply device comprising:
a battery controller configured to control a battery module;
a DC-DC converter;
a duct configured to send air to the DC-DC converter;
a module case in which the battery module is mounted; and
a switch structure, wherein
the switch structure comprises a cutoff switch configured to be manually operated to cut off the battery module from a power electronic component,
the cutoff switch is disposed on a side of a passenger seat inside a console box disposed between a driver seat and the passenger seat of a vehicle,
the battery controller and the duct are arranged along a vertical direction inside the console box,
an upper surface of the module case has a protrusion located inside the console box, and
the cutoff switch is provided on a side surface of the protrusion.

7. A power supply device comprising:
a module case in which a battery module is mounted; and
a switch structure, wherein
the switch structure comprises a cutoff switch configured to be manually operated to cut off the battery module from a power electronic component,
the cutoff switch is disposed on a side of a passenger seat inside a console box disposed between a driver seat and the passenger seat of a vehicle,
an upper surface of the module case has a protrusion located inside the console box, and
the cutoff switch is provided on a side surface of the protrusion.
